(19) United States
(12) Patent Application Publication
(10) Pub. No.: US 2025/0349697 A1
(43) Pub. Date: Nov. 13, 2025

(54) Package And Method of Manufacturing A Package

(71) Applicant: AT&S Austria Technologie & Systemtechnik Aktiengesellschaft, Leoben (AT)

(72) Inventor: Jeesoo MOK, Leoben (AT)

(21) Appl. No.: 18/868,736

(22) PCT Filed: May 25, 2023
(86) PCT No.: PCT/EP2023/064135

§ 371 Date: Nov. 23, 2024

(30) Foreign Application Priority Data
May 26, 2022 (CN) 202210589649.6

(51) Int. Cl. H01L 23/498; H01L 21/48

(52) U.S. Cl. CPC H01L 23/49838; H01L 21/486; H01L 23/49827

(57) ABSTRACT

A package includes an inorganic core having at least one through hole, and at least one organic board with an at least partially organic dielectric matrix and at least one electrically conductive vertical through connection extending vertically through the at least partially organic dielectric matrix. The at least one organic board is at least partially embedded in the at least one through hole, and an electric connection between a top side and a bottom side of the inorganic core is established by the at least one vertical through connection.

### CROSS REFERENCE TO RELATED APPLICATIONS

This application is a national stage application, filed under 35 U.S.C. § 371, of International Patent Application No. PCT/EP2023/064135, filed on May 25, 2023, claiming priority of Patent Application No. 202210589649.6 filed on May 26, 2022, in China, the disclosures of these patent applications being incorporated by reference herein in their entirety.

### TECHNICAL FIELD

The disclosure relates to a package and to a method of manufacturing a package.

### TECHNOLOGICAL BACKGROUND

In the context of growing product functionalities of component carriers equipped with one or more components and increasing miniaturization of such components as well as a rising number of components to be connected to the component carriers such as printed circuit boards, increasingly more powerful array-like components or packages having several components are being employed, which have a plurality of contacts or connections, with ever smaller spacing between these contacts. In particular, component carriers shall be mechanically robust and electrically reliable so as to be operable even under harsh conditions.

Conventional approaches of forming component carrier-type packages are still challenging.

### SUMMARY OF THE DISCLOSURE

There may be a need to form a compact and reliable component carrier-type package.

According to an exemplary embodiment of the disclosure, a package is provided which comprises an inorganic core having at least one through hole, and at least one organic board comprising an at least partially organic dielectric matrix and at least one electrically conductive vertical through connection extending vertically through the at least partially organic dielectric matrix, wherein the at least one organic board is at least partially embedded in the at least one through hole, and wherein an electric connection between a top side and a bottom side of the inorganic core is established by the at least one vertical through connection.

According to another exemplary embodiment of the disclosure, a method of manufacturing a package is provided, wherein the method comprises forming at least one through hole in an inorganic core, providing at least one organic board with an at least partially organic dielectric matrix and at least one electrically conductive vertical through connection extending through the at least partially organic dielectric matrix, embedding at least part of the at least one organic board in the at least one through hole, and establishing an electric connection between a top side and a bottom side of the inorganic core by the at least one vertical through connection.

In the context of the present document, the term “package” may particularly denote any support structure which is capable of accommodating one or more components thereon and/or therein for providing mechanical support and/or electrical connectivity. In other words, a package may be configured as a mechanical and/or electronic carrier for components. In particular, a package may be a component carrier-type device. Such a component carrier may be one of a printed circuit board, an organic interposer, and an IC (integrated circuit) substrate. A component carrier may also be a hybrid board combining different types of component carriers.

In the context of the present document, the term “inorganic core” may particularly denote a central carrier structure of the package which comprises inorganic material. In particular, dielectric material of the inorganic core or even the entire inorganic core may be made exclusively or at least substantially exclusively from inorganic material. In another embodiment, the inorganic core may comprise inorganic dielectric material and additionally another dielectric material. An inorganic compound may be a chemical compound that lacks carbon-hydrogen bonds or a chemical compound that is not an organic compound. Examples of inorganic core materials are glass (in particular silica-based glass), a ceramic (such as aluminum nitride and/or aluminum oxide), and a material comprising a semiconductor (such as silicon oxide, silicon, silicon carbide, gallium nitride, etc.).

In the context of the present document, the term “organic board” may particularly denote a block-, strip- or plate-shaped structure which comprises a dielectric material having an organic compound. In particular, dielectric material of the organic board may be made exclusively or at least substantially exclusively from organic material. In another embodiment, the organic board may comprise organic dielectric material and additionally another dielectric material. An organic compound may be a chemical compound that contains carbon-hydrogen bonds. For example, the organic board may comprise an organic resin material, an epoxy material, etc. In particular, printed circuit board (PCB) dielectrics or integrated circuit (IC) substrates dielectrics may be dielectrics used for the organic board. Moreover, said organic board comprises additionally at least one electrically conductive vertical through connection.

In the context of the present document, the term “electrically conductive vertical through connection” may particularly denote one or more vertically extending metallic structures, for example comprising or consisting of copper. The term “vertical” may denote a thickness direction of the package, the core or the board. Examples for an electrically conductive vertical through connection may be a metal pillar (in particular a copper pillar), a metal cylinder, a metal-filled drill hole (such as a plated laser via or a plated mechanically drilled via), an array of vertically stacked vias, or a stacked via-pad sequence. In one embodiment, all electrically conductive elements of the organic board may be vertical through connections. However, in an embodiment, the at least one organic board may additionally comprise one or more horizontal electrical connection elements. A corresponding horizontal electrical connection element may be located at a surface of the organic board and/or in an interior of the organic board.

In the context of the present document, the term “dielectric matrix” may particularly denote an electrically insulating body with hole or holes (in particular comprising at least one vertical through hole) which may be filled with metallic material.

In the context of the present document, the term “at least partially embedded” may particularly denote fully embedded or only partially embedded. In a fully embedded embodiment, the entire vertical spatial range between upper end and lower end of the organic board is located inside of the inorganic core. In one embodiment, the upper end of the at least partially embedded organic board may be in alignment with an upper main surface of the inorganic core and/or the lower end of the at least partially embedded organic board may be in alignment with a lower main surface of the inorganic core. In another embodiment, the upper end of the at least partially embedded organic board may be located below an upper main surface of the inorganic core and/or the lower end of the at least partially embedded organic board may be located above a lower main surface of the inorganic core. However, it is also possible that an upper end portion of the organic board protrudes vertically beyond an upper main surface of the inorganic core and/or that a lower end portion of the organic board protrudes vertically below an lower main surface of the inorganic core.

According to an exemplary embodiment of the disclosure, a package architecture is provided in which an electrically conductive front to back side connection between two opposing main surfaces of an inorganic core is established by one or more electrically conductive vertical through connections extending through an organic board embedded in said inorganic core. Consequently, a very short z-connection path may be created allowing electric signals and/or electric power to propagate vertically through the package. Furthermore, this may lead to a compact design of the package. In view of the achieved very short connection path, losses of electric energy and signal losses may be very small. Advantageously, this may lead to an improved signal integrity and to a lower amount of dissipated heat. As a result, undesired phenomena such as delamination and warpage caused by thermal stress may be reliably suppressed. Thus, a high thermal and electrical reliability may be achieved. Moreover, a cheap and simple inorganic core may form the mechanical base of the package, wherein one or more inlay-type organic boards may define an electric interconnection in a vertical direction. This allows to manufacture the package with low effort and high performance.

### OVERVIEW OF EMBODIMENTS

In the following, further exemplary embodiments of the package and the method will be explained.

In an embodiment, an electrical connection may be established between the inorganic core and the organic board in a horizontal plane (i.e. along an XY-direction). Thus, the inorganic core and the organic board may be electrically coupled for flow of electric signals and/or power horizontally or perpendicular to the vertical direction.

In an embodiment, the above-mentioned electric connection between top side and bottom side of the inorganic core may be established exclusively by the at least one vertical through connection. This may be an extremely easy way of electrically connecting opposing main surfaces of the inorganic core. However, alternatively, said electric connection between top side and bottom side of the inorganic core may be established by the at least one vertical through connection in combination with at least one optional horizontal electrical connection element of the organic board. This may further increase the flexibility of the electric interconnection, for instance may allow to integrate a redistribution structure or a fan-structure in the organic board.

In an embodiment, the package comprises a first laminated layer stack on one of the top side and the bottom side of the inorganic core. In the context of the present document, the term “stack” may particularly denote an arrangement of multiple planar layer structures which are mounted in parallel on top of one another. Furthermore, the term “layer structure” may particularly denote a continuous layer, a patterned layer or a plurality of non-consecutive islands within a common plane. Lamination may be carried out by applying pressure and/or heat. The inorganic core with one or more integrated organic boards may form a robust mechanical base or support and may electrically connect to a top-sided laminated layer stack.

In an embodiment, the first laminated layer stack comprises a redistribution structure, such as a redistribution layer (RDL). A redistribution structure may function as an electric interface between large electrically conductive structures of the stack, as characteristic for component carrier-technology, and smaller electrically conductive structures of a surface mounted component, as characteristic for semiconductor technology. In particular, such a redistribution structure may taper from an interior of the package towards an exterior main surface of the first laminated layer stack (see for instance FIG. 1).

In an embodiment, electrically conductive traces of the first laminated layer stack are directly electrically connected with the at least one vertical through connection and/or with at least one horizontal connection element of the at least one organic board. In the context of the present document, the term “trace” may particularly denote an elongate element of an electrically conductive layer structure. For instance, such an elongate element may be straight, curved and/or angled. An example of a trace element is a wiring. For instance, a trace element may interconnect connection elements, components, vertical through connections and/or other trace elements. For example, a trace element may extend within a horizontal plane. In the context of the present document, the term “connection element” may particularly denote a laminar element of an electrically conductive layer structure. For instance, such a laminar element may be flat or two-dimensional, such as a pad. However, a connection element may also be three-dimensional and/or may extend vertically, such as a pillar or cylinder. For instance, a connection element may contribute to a connection between stack and organic board, in particular by forming part of the stack and being connected with another connection element of said organic board. For example, a connection element may also be connected to other connection elements, components, vertical through connections and/or traces. A direct connection between one or more traces and one or more vertical through connections may keep the electric connection path short, which may promote signal integrity and prevent excessive heating by ohmic losses.

In an embodiment, an integration density of electrically conductive elements in a first portion (such as one or more entire layer structures) of the first laminated layer stack (which first portion may face away from the inorganic core and the at least one organic board) is larger than in a second portion (such as one or more other entire layer structures) of the first laminated layer stack (which second portion may face the inorganic core and the at least one organic board). In this context, the term “integration density” may denote a number of electrically conductive elements (in particular trace elements (such as wiring structures), connection elements (such as pads) and/or vertical through connections (such as metallic vias)) per area or volume of the respective portion. Hence, the amount of electrically conductive elements in a higher density portion may be higher than the amount of electrically conductive elements in a lower density portion. Thus, integration density may mean a quantity of electrically conductive elements per area or volume. The integration density in a lower density portion can be less than in a higher density portion. Correspondingly, the line space ratio and/or line pitch may be higher in a lower density portion than in a higher density portion. The term “line space ratio” may denote a pair of characteristic dimensions of an electrically conductive trace element, i.e. a characteristic line width of one electrically conductive trace element and a characteristic distance between adjacent electrically conductive trace elements. The term “line pitch” may denote the distance between corresponding edges of two adjacent metal structures. Since manufacture of a stack portion with high integration density may involve a larger effort than manufacture of a stack portion with low integration density, it is advantageous when a high integration density is only manufactured in the first laminated layer stack where needed from a functional point of view. In other portions of the first laminated layer stack in which a low integration density is sufficient for fulfilling a desired function, a simplified manufacturing process can be carried out.

In an embodiment, the first portion faces away from the inorganic core and the second portion faces the inorganic core. An exposed surface of the first portion may serve for surface mounting one or more components, such as semiconductor chips. Hence, a higher integration density in said first portion may be advantageous for connecting electronic components with low line pitch and low line space ratio. In contrast to this, the opposing surface of the first portion which is connected to the inorganic core and the at least one organic board may be equipped with a lower integration density for reducing the overall manufacturing effort.

In an embodiment, the package comprises at least one component, in particular at least one semiconductor chip, surface mounted on the first laminated layer stack. It is also possible that a plurality of components is surface mounted on the first laminated layer stack. Moreover, it is possible that at least one component is embedded in the package. The above-mentioned surface mounted component may be attached to an exterior main surface of the first laminated layer stack and may be connected here electrically and mechanically. Surface mounting of a component may simplify the manufacture of the component carrier and removal of heat from the surface mounted component(s) during operation of the component carrier.

In an embodiment, the package comprises a second laminated layer stack on the other one of the top side and the bottom side of the inorganic core. The inorganic core with one or more integrated organic boards may also form a robust mechanical base or support and may provide an electric interconnection for a bottom-sided laminated layer stack. In view of the high mechanical robustness of the inorganic core, even an asymmetric build-up on both opposing main surfaces thereof may be possible. An asymmetric build-up may relate to the first and second laminated layer stacks having different properties (such as different materials, different thicknesses, different integration density) and/or a different number of layer structures. Conventionally, an asymmetric build-up may involve the risk of warpage. However, due to the pronounced mechanical robustness in particular of the inorganic core (for example a glass plate), an asymmetric build-up is possible according to exemplary embodiments without the risk of warpage. The whole construction of the package may contribute to a compensation of structural differences between the two sides to avoid warpage.

For example, an exposed main surface of the second laminated layer stack may function as a connection surface to a mounting base on which the exposed main surface of the second laminated layer stack may be mounted. For instance, such a mounting base may be a printed circuit board (PCB). For this purpose, it is possible that an electrically conductive connection structure is provided at said exposed main surface of the second laminated layer stack. Said electrically conductive connection structure may comprise for example solder structures, such as solder balls or solder paste. Alternatively, sinter structures, electrically conductive glue and/or metallic pillars (for example copper pillars) may be used for accomplishing such an electric connection.

In an embodiment, the second laminated layer stack provides a grid array interface. In particular, said grid array interface may be a ball grid array interface or a land grid array interface. Land Grid Array (LGA) and Ball Grid Gray (BGA) are both Surface Mount Technologies (SMT), in particular for printed circuit boards or motherboards. They basically define how the package will actually be mounted, in particular on a PCB or a motherboard's socket. Essentially, the most basic difference between the two is that an LGA based package can be plugged in and out of the PCB or motherboard and can also be replaced. A BGA based package, however, may be soldered on the PCB or motherboard and thus cannot be plugged out or replaced. A Ball Grid Array, on the other hand, may have spherical contacts which are then soldered onto the PCB or motherboard. An LGA type package may be placed on top of a socket on a PCB or motherboard. In this context, the package may have flat surface contacts whereas the PCB or motherboard socket may have pins.

In an embodiment, electrically conductive traces of the second laminated layer stack are directly electrically connected with the at least one vertical through connection and/or with at least one horizontal connection element of the at least one organic board. This may lead to extremely short vertical connection paths, and consequently excellent signal quality, efficient heat management and compact design.

In an embodiment, an integration density (in particular an average integration density) of electrically conductive elements in the first laminated layer stack is larger than an integration density (in particular an average integration density) of electrically conductive elements in the second laminated layer stack. More specifically, the higher integration density in the first laminated layer stack may be adjusted to the demanding requirements of semiconductor technology, i.e. to small line pitch and small line space ratio at a connection surface of an electronic component (such as a semiconductor chip) to be surface mounted on the first laminated layer stack. On the other hand, the lower integration density in the second laminated layer stack may be fitted to the relaxed requirements of printed circuit board technology, i.e. to larger line pitch and larger line space ratio at a connection surface of a mounting base (such as a PCB) on which the second laminated layer stack is to be mounted. The asymmetry-and consequently increased mechanical stress-involved with the different integration densities on the two opposing main surfaces of the inorganic core may become feasible due to the high mechanical robustness of the inorganic core. Despite such mechanical (and thermal) stress, issues with warpage and delamination may nevertheless be avoided thanks to the inorganic core.

In an embodiment, the package comprises a mounting base, such as a component carrier, in particular a printed circuit board (PCB), on which the second laminated layer stack is mounted. However, another mounting base or carrier may be implemented as well on the bottom side of the package.

In an embodiment, at least one of a first width over which electric signals propagate through the first laminated layer stack and a second width over which electric signals propagate through the second laminated layer stack is larger than a constricted width over which electric signals propagate through the at least one organic board. In this context, the term “first width” may denote a horizontal spatial range of the first laminated layer stack over which electric signals or electric power propagate during operation of the package. More specifically, said first width may extend from an outmost electrically conductive element on one side of the first laminated layer stack to an opposing outmost electrically conductive element on an opposing other side of the first laminated layer stack, which electrically conductive elements carry an electric signal or current when the package is in use. Correspondingly, the term “second width” may denote a horizontal spatial range of the second laminated layer stack over which electric signals or electric power propagate during operation of the package. More specifically, said second width may extend from an outmost electrically conductive element on one side of the second laminated layer stack to an opposing outmost electrically conductive element on an opposing other side of the second laminated layer stack, which electrically conductive elements carry an electric signal or current when the package is in use. Accordingly, the term “constricted width” may denote a horizontal spatial range of the inorganic core and the assigned at least one organic board over which electric signals or electric power propagate during operation of the package. More specifically, said constricted width may extend from an outmost electrically conductive vertical through connection on one side of the inorganic core and the assigned at least one organic board to an opposing outmost electrically conductive vertical through connection on an opposing other side of the inorganic core and the assigned at least one organic board, which electrically conductive through connections carry an electric signal or current when the package is in use. Descriptively speaking, the spatial range of propagating electricity may be laterally constricted in the inorganic core with at least one organic board therein, compared with each of the first laminated layer stack and the second laminated layer stack. To put it shortly, the inorganic core with at least one organic board may be the spatial bottleneck for electric signals and electric power traveling vertically through the package. Hence, the described guidance of electricity vertically through the package may channel electricity in a defined way. For instance, the constricted width may be at least 20%, in particular at least 30%, smaller than the first width and/or the second width.

In an embodiment, at least one of the at least one vertical through connection extending along the entire path between a top side and a bottom side of the respective organic board may be a single integral continuous structure. Such a single integral continuous structure may be for example a single pillar or a single cylindrical body having a length corresponding to the overall thickness of the respective organic board. Advantageously, this allows a very simple manufacture of the organic board with integrated vertical through connection(s) and contributes to very short electric paths in z-direction. For instance, such a vertical through connection embodied as single integral continuous structure may have an aspect ratio (i.e. a ratio between vertical length and horizontal diameter) of at least 1, in particular of at least 2, more particularly of at least 3.

In an embodiment, the package comprises a filling medium, in particular resin or magnetic paste, at least partially filling at least one gap between a wall of the at least one organic board and a further wall of the inorganic core delimiting the at least one through hole. In one embodiment, such a filling medium may be a dielectric glue inserted into the gap. For instance, such a glue can be cured by pressure and/or heat. Additionally or alternatively, such a filling medium may be resin from an at least partially uncured electrically insulating layer structure (such as a resin of prepreg sheet) laminated on the top side and/or on the bottom side of the inorganic core with inserted at least one organic board. By the application of pressure and/or heat, such a resin may become flowable and may flow in the gap before resolidifying by curing. Also said curing process may be triggered by the application of pressure and/or heat. By filling such a gap, void spaces within the readily manufactured package may be prevented which may improve the mechanical integrity and thus reliability of the package. Furthermore, such a filling medium may glue in place an organic board in a through hole of the inorganic core and may thereby promote a correct alignment of the various constituents of the package. Also, the adhesion between the organic board(s) and the inorganic core may contribute to such advantageous effects.

In an embodiment, the filling medium bridges said wall of the at least one organic board and said further wall of the inorganic core, and said wall has a different level of surface roughness compared with said further wall. Hence, the filling medium (in particular resin) may balance out roughness differences between opposing side walls of inorganic core and organic board.

In an embodiment, the package comprises at least one dielectric adhesion promoter layer, on at least one of the top side and the bottom side of the inorganic core. For example, such an adhesion promoter may be a chemical adhesion promoter (such as silane) or a morphological adhesion promoter (promoting adhesion due to an increased surface area). An interface between a respective main surface of the inorganic core on the one hand and a corresponding first or second laminated layer stack (which may comprise organic material) on the other hand may involve a material bridge. At such a material bridge, proper adhesion may be challenging. In order to avoid issues resulting from poor adhesion, such as delamination, an adhesion promoter layer may be sandwiched between the inorganic core and at least one of the laminated layer stacks. This may further improve the reliability of the package.

In an embodiment, the inorganic core is free of electrically conductive through connections, in particular is purely dielectric. This allows the manufacture of the inorganic core with lowest effort, for instance as glass plate, a ceramic plate or a silicon plate, with one or more through holes.

Alternatively, the inorganic core may comprise one or more electrically conductive elements, for example electrically conductive through connections (such as through glass vias/TGV). More generally, the inorganic core may then comprise traces, paths and/or vertical through connections. By taking this measure, sophisticated electric applications may be supported. There are benefits of adding one or more TGVs: From a structural point of view, TGVs can provide a short and direct vertical interconnection for efficient electrical transmission. The direct electrical transmission through the TGV can lead to a proper signal integrity due to the glass property. This may result in a low loss as well and thus has significant advantages for high frequency applications.

Moreover, it should be added that through hole formation using certain kinds of materials may cause damage. If it is intended to directly pattern the glass with an electrical connection structure, it may be difficult to use a normal process and it may be necessary to use a sputtering tool. Compared to such approaches, a benefit of embodiments of the disclosure is quite significant for high volume manufacturing from a technical point of view.

In an embodiment, the inorganic core has at least two through holes, wherein the package comprises at least two organic boards, each comprising an at least partially organic dielectric matrix and at least one electrically conductive vertical through connection extending vertically through the at least partially organic dielectric matrix, and wherein each of the organic boards is embedded in a respective one of the through holes so that the organic boards are arranged side-by-side. To put it shortly, a plurality of organic boards may be inserted into a plurality of through holes of the inorganic core. Two or more organic boards may thus be located at the same vertical level in the plate-shaped inorganic core. Additionally or alternatively, it is also possible that two or more organic boards are vertically stacked in the same through hole in the inorganic core. When two or more through holes are formed in the inorganic core, it is also possible that one or more of said through holes are filled with one or more organic boards, whereas one or more other of said through holes may accommodate another inlay, such as a semiconductor chip or another component. In other words, the inorganic core may be also used for embedding one or more additional components. Furthermore, the implementation of an inorganic core may improve the uniformity of electrical structures. Due to the stiffness or hardness of the inorganic material, the support of the board can reduce the shrinkage of the device during processing, which may lead to a precise alignment performance of the inner layers.

In an embodiment, the at least one organic board comprises at least two electrically conductive vertical through connections extending in parallel through the at least partially organic dielectric matrix. By taking this measure, two or more parallel electric paths may be created in a single organic board. This may allow to further refine the electric interconnection architecture in the inorganic core and may increase the bandwidth in terms of signal transmission and power transmission.

In an embodiment, a vertical thickness of the inorganic core is at least 500 μm, in particular at least 800 μm. Advantageously, the inorganic core may be embodied as a thick plate. Such a thick inorganic core may provide a robust mechanical support for the other constituents of the package and may suppress undesired phenomena such as warpage. Furthermore, the provision of such a thick inorganic core may even tolerate an asymmetric build-up on both opposing main surfaces thereof without deterioration of the mechanical integrity of the package.

In an embodiment, the electric connection between the top side and the bottom side of the inorganic core is established exclusively by the at least one vertical through connection. Thus, no other metallic constituents of the inorganic core and the at least one organic board are necessary in such an embodiment. This may enable a very simple construction and manufacture of the package.

In an embodiment, the respective stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier-type package may be shaped as a plate. This contributes to the compact design, wherein the component carrier nevertheless provides a large basis for mounting components thereon. Furthermore, in particular a naked die as example for an embedded electronic component, can be conveniently embedded, thanks to its small thickness, into a thin plate such as a printed circuit board.

In an embodiment, the package comprises a printed circuit board, a substrate (in particular an IC substrate), or an interposer.

In the context of the present document, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present document, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular coated with supra-conductive material or conductive polymers, such as graphene or poly (3,4-ethylenedioxythiophene) (PEDOT), respectively.

At least one further component may be embedded in and/or surface mounted on the respective stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the package is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a package according to an exemplary embodiment of the disclosure.

FIG. 2, FIG. 3, FIG. 4, FIG. 5, FIG. 6, FIG. 7, FIG. 8, FIG. 9, FIG. 10, FIG. 11 to FIG. 12 illustrate cross-sectional views of structures obtained during carrying out a method of manufacturing a package, shown in FIG. 12, according to an exemplary embodiment of the disclosure.

### DETAILED DESCRIPTION OF THE ILLUSTRATED EMBODIMENTS

The illustrations in the drawings are schematically presented. In different drawings, similar or identical elements are provided with the same reference signs.

Before referring to the drawings, exemplary embodiments will be described in further detail, some basic considerations will be summarized based on which exemplary embodiments of the disclosure have been developed.

According to an exemplary embodiment of the disclosure, a package may be formed based on an inorganic core with one or more organic boards embedded therein partially or entirely. One or more metallic vertical through connections extending vertically through the respective organic board (being accommodated in the inorganic core) electrically couple a top side and a bottom side of the inorganic core. Hence, one or more single-body oblong metallic structures extending preferably straight through core and board in vertical direction may electrically couple (in particular alone) laminated layer stacks on opposing main surfaces of the core and the one or more boards. Such an interconnection architecture may ensure a short vertical path length and hence a proper transmission of electricity in the form of signals and/or power as well as a compact design. Furthermore, this may reduce ohmic losses and may thus relax requirements concerning heat management. The mechanically stable core in combination with a strongly limited dissipation of heat in an interior of the package may also suppress undesired phenomena such as delamination and warpage. Thus, a high mechanical, electrical and thermal reliability may be achieved.

More specifically, an exemplary embodiment provides a package having a patterned glass carrier fan out substrate. In an embodiment, a patterned glass carrier core with at least one cavity may be provided to improve characteristics concerning layer routing and warpage. A corresponding package may have an asymmetric build-up with a higher integration density fan out redistribution layer on the top side and a lower integration density mounting base interface (in particular ball grid array/BGA, interface) at the bottom side. Such a design may lead to a better warpage management of the asymmetric build-up with glass carrier core. Furthermore, a fan out package according to an exemplary embodiment of the disclosure may be manufactured with a high yield, since a surface mounted component may be applied by a chip last assembly. For example, a known-good component may be mounted at the very end of the manufacturing process of a known-good package. Furthermore, improved packaging conditions with higher stiffness and chip last packaging architecture may be made possible.

For manufacturing a package according to an exemplary embodiment of the disclosure, a copper clad laminate (CCL) glass carrier may be used as inorganic core forming the basis of the package to be manufactured. Said inorganic core may be treated with a subtractive patterning process for structuring the coating of the glass carrier and for forming at least one through hole therein. Subsequently, an organic board (such as a PCB core piece) may be embedded in the through hole of the inorganic core. Thereafter, a top-sided high-density fan out structure may be formed as first laminated layer stack on the top side of the core and board. Furthermore, a bottom-sided lower density ball grid array structure may be formed as second laminated layer stack on the bottom side of the core and board. After that, at least one surface mounted component may be assembled on the first laminated layer stack by carrying out a chip last packaging process.

Fan out packages according to exemplary embodiments may be used for example for mobile phones and related electronic devices.

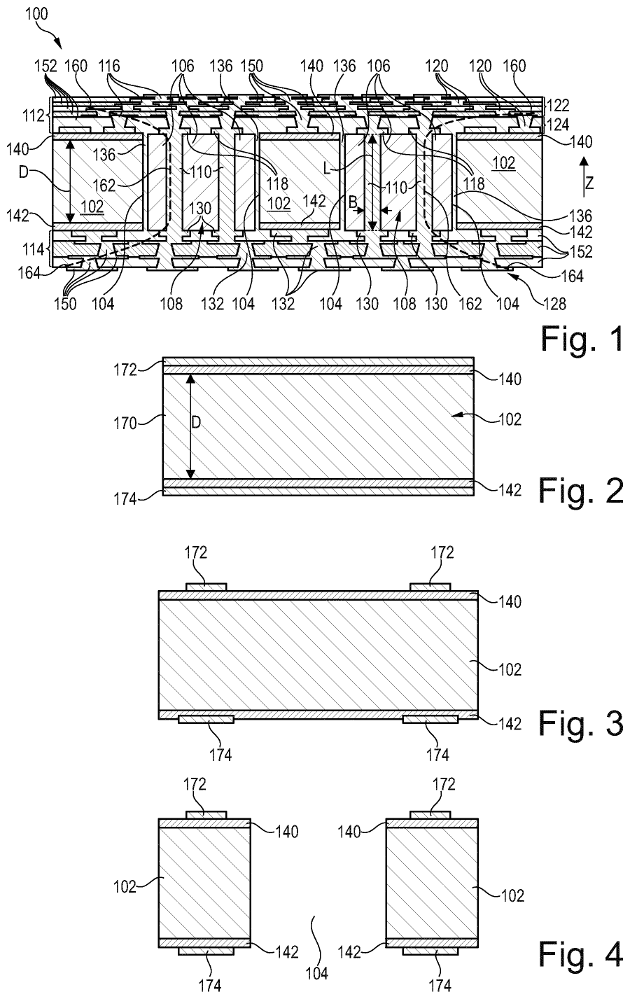

FIG. 1 illustrates a cross-sectional view of a package 100 according to an exemplary embodiment of the disclosure.

The illustrated package 100 comprises a central inorganic core 102, which may be made for instance of glass, a ceramic or silicon. Vertical through holes 104 are formed to extend through the entire thickness of the inorganic core 102. As shown, the inorganic glass body of the inorganic core 102 can be provided with a large thickness, D, of for instance at least 800 um. This may ensure a high mechanical stability of the inorganic core 102.

According to FIG. 1, each through hole 104 accommodates a respective organic board 108, such as a piece of the PCB. A filling medium 136, such as resin, completely fills gaps 138 (see FIG. 7) between walls of the respective organic board 108 and further walls of the inorganic core 102 (wherein the further walls delimit the through holes 104). Advantageously, the filling medium 136 may bridge said walls of the organic board 108 and said further walls of the inorganic core 102, and the said walls of the organic board 108 have different levels of roughness compared with said further walls of the inorganic core 102. In one embodiment, the roughness of the walls of the organic board 108 is higher than the roughness of the walls of the inorganic core 102. In another embodiment, the roughness of the walls of the organic board 108 is lower than the roughness of the walls of the inorganic core 102. Moreover, the provision of the filling medium 136 avoids empty volumes in an interior of the package 100 which may improve reliability.

Preferably, each organic board 108 is embedded completely in a respective through hole 104. This provides planar or substantially planar surfaces which simplify a subsequent lamination process. As shown, the upper main surface of a respective organic board 108 is basically in alignment with an upper main surface of the inorganic core 102. Correspondingly, the lower main surface of a respective organic board 108 is basically in alignment with a lower main surface of the inorganic core 102. As a result, the inorganic core 102 together with the organic boards 108 form a plate-like structure with substantially planar upper and lower main surfaces. For instance, the organic board 108 may be a printed circuit board (or a piece of a PCB) or an integrated circuit (IC) substrate.

As shown in FIG. 1, each organic board 108 comprises an at least partially organic dielectric matrix 106 and a plurality of parallel electrically conductive vertical through connections 110 extending vertically through the entire at least partially organic dielectric matrix 106. For instance, the dielectric matrix 106 comprises an organic resin (for example epoxy resin) and optionally reinforcing particles (such as glass fibers). In the shown embodiment, the vertical through connections 110 may be elongate metal cylinders, such as copper pillars. Such vertical through connections 110 may be pre-formed integral bodies which are then inserted into vertical through holes formed in a respective dielectric matrix 106. It is however also possible that the vertical through connections 110 are formed in a vertical through hole of the respective organic board 108 by plating (for instance by electroless plating followed by galvanic plating). As shown, the vertical through connections 110 are formed with an aspect ratio of larger than 1, for instance about 5. The aspect ratio may be defined as the ratio between vertical length, L, divided by horizontal diameter, B, of a respective vertical through connections 110.

As shown, an electric connection between a top side and a bottom side of the inorganic core 102 with inserted organic boards 108 may be established exclusively by the vertical through connections 110, and therefore in a very simple way.

This has advantages: Firstly, the fact that exclusively the vertical through connections 110 accomplish the electric connection between the top side and the bottom side of the inorganic core 102 with inserted organic boards 108 allows to embody the inorganic core 102 with a very simple construction, for instance as a simple glass plate without metallic constituents. Furthermore, the integral formation and vertical extension of the vertical through connections 110 create extremely short electric paths in z-direction. This may lead to small signal loss and therefore high signal quality of electric signals propagating through the vertical through connections 110. In addition, this may result in small ohmic losses and consequently in a small heat dissipation inside of the package 100 Consequently, thermal stress inside of package 100 may be low, which may advantageously avoid undesired phenomena such as delamination. Moreover, the inorganic material and the large vertical thickness, D, of the inorganic glass body of the inorganic core 102 may provide reliable mechanical support for the other constituents of the package 100. Hence, although an asymmetric build-up is formed on both opposing main surfaces of the inorganic core 102 according to FIG. 1 (see reference signs 112, 114 described below in further detail), package 100 is not prone to warpage due to the high mechanical stability of the inorganic core 102.

Again referring to FIG. 1, package 100 comprises a first laminated layer stack 112 on the top side of the inorganic core 102 and of the organic boards 108. Moreover, package 100 further comprises a second laminated layer stack 114 on the bottom side of the inorganic core 102 and of the organic boards 108. In the shown embodiment, the first laminated layer stack 112 and the second laminated layer stack 114 have a significantly different build-up, so that package 100 has an asymmetric design. The different build-ups of layer stacks 112, 114 are created in view of their different technical functions, as described below. However, contrary to conventional approaches with asymmetric build-up, the package 100 does not suffer from warpage due to the high mechanical stability provided by the thick core 102 made of inorganic material.

Each of the laminated layer stacks 112, 114 is composed of electrically conductive layer structures 150 and of electrically insulating layer structures 152. As shown, the electrically conductive layer structures 150 may comprise patterned or continuous copper foils. As shown as well, the electrically conductive layer structures 150 may further comprise vertical through connections, for example copper filled laser vias which may be created by plating. The one or more electrically insulating layer structures 152 may comprise a respective resin (such as a respective epoxy resin), preferably comprising reinforcing particles therein (for instance glass fibers or glass spheres). For instance, the electrically insulating layer structures 152 may be made of prepreg or FR4.

Next, the first laminated layer stack 112 will be described in further detail. As shown, the first laminated layer stack 112 comprises a redistribution structure 116. Referring to FIG. 1, the electrically conductive layer structures 150 of the first laminated layer stack 112 form an upwardly tapering structure. Thus, a mutual distance between adjacent electrically conductive layer structures is smaller in the upper portion of the first laminated layer stack 112 compared to the lower portion of the first laminated layer stack 112. Consequently, the higher integration density in said upper portion may correspond to the small line pitch of a connection surface of an electronic component 126 which may be surface mounted on the first laminated layer stack 112 (see FIG. 11). Furthermore, the lower integration density in said lower portion may correspond to the larger line pitch of a connection surface of a mounting base 134 (such as a printed circuit board or another component carrier) which may be connected to a bottom surface of the second laminated layer stack 114 (see FIG. 12). Thus, the redistribution structure 116 may translate or form an interface between the smaller dimensions of semiconductor technology and the larger dimensions of component carrier technology.

Furthermore, FIG. 1 shows that electrically conductive traces 118 of the first laminated layer stack 112 are directly electrically connected with the vertical through connections 110, i.e. without other structures in between. This may additionally contribute to short electric connection paths.

As can be taken from FIG. 1 as well, an integration density of electrically conductive elements 120 in a first portion 122 of the first laminated layer stack 112 is larger than in a second portion 124 of the first laminated layer stack 112. As shown, the first portion 122 faces away from the inorganic core 102 and the second portion 124 faces the inorganic core 102. Advantageously, the higher manufacturing effort for creating higher density electrically conductive elements 120 in the first portion 122 needs to be provided only where functionally needed, i.e. at the interface to a surface mounted component 126 with high integration density connection elements. Remote from such a surface mounted component 126, i.e. in second portion 124, a lower integration density of electrically conductive elements 122 is sufficient which may reduce the overall manufacturing effort. In the embodiment of FIG. 1, the layer-type first portion 122 relates to different layer structures 150, 152 compared with the layer-type second portion 124. Each of the first portion 122 and the second portion 124 extends over the entire width of the first laminated layer stack 112.

Next, the second laminated layer stack 114 will be described in further detail. As shown, the second laminated layer stack 114 provides a ball grid array (BGA) interface 128 at its exposed lower main surface. Here, a plurality of solder balls or the like may be provided as electrically conductive connection structures 154 (see FIG. 10). A mounting base 134, such as a printed circuit board, may be connected to a lower main surface of the package 100 of FIG. 1 using the electrically conductive connection structures 154 (see FIG. 12).

As shown as well, electrically conductive traces 130 of the second laminated layer stack 114 are directly electrically connected with the vertical through connection 110 of the organic boards 108. Also, this measure may additionally contribute to short electric connection paths.

Furthermore, an integration density of electrically conductive elements 120 in the first laminated layer stack 112 is larger than an integration density of electrically conductive elements 132 in the second laminated layer stack 114. This reflects the different functions of the first laminated layer stack 112 and the second laminated layer stack 114. Since the first laminated layer stack 112 is provided for surface mounting a component 126 such as a semiconductor chip, a high integration density is necessary or at least highly advantageous in the first portion 122. In contrast to this, the second laminated layer stack 114 serves for being connected to a PCB-type mounting base 134, so that a smaller integration density is sufficient and even advantageous here. Although this design leads to an asymmetry of the build-up of the first laminated layer stack 112 compared with a build-up of the second laminated layer stack 114, issues with warpage will be strongly reduced in view of the robust material and high thickness of the inorganic core 102.

The design of the electrically conductive elements of package 100 according to FIG. 1 leads to a specific attribute: As shown, a first width (defined by limits according to reference signs 160) over which electric signals propagate through the first laminated layer stack 112 and a second width (defined by limits according to reference signs 164) over which electric signals propagate through the second laminated layer stack 114 are both larger than a constricted width (defined by limits according to reference signs 162) over which electric signals propagate through the organic boards 108. To put it shortly, the electric connection paths have a lateral bottleneck in the inorganic core 102 and widen up laterally on both vertical sides thereof. Consequently, electricity is channeled in a defined way in a vertical direction according to FIG. 1.

Further advantageously, a first dielectric adhesion promoter layer 140 is provided between the top side of the inorganic core 102 on the one hand and the first laminated layer stack 112 on the other hand. Correspondingly, a second dielectric adhesion promoter layer 142 is provided between the bottom side of the inorganic core 102 on the one hand and the second laminated layer stack 114 on the other hand. The adhesion promoter layers 140, 142 promote adhesion at the material bridges between inorganic core 102 and the laminated layer stacks 112, 114. This efficiently suppresses undesired delamination and improves the mechanical reliability of the package 100.

The asymmetric build-up of package 100 on the two opposing main surfaces of core 102 with embedded board 108 allows to manufacture a high density fan out redistribution layer (see reference sign 116) on the top side and a low-density BGA interface on the bottom side without compromising on mechanical reliability. A proper warpage management of the asymmetric build-up may be achieved thanks to the provision of the inorganic core 102. Furthermore, the embedded organic boards 108 within the patterned glass carrier constituting the inorganic core 102 according to FIG. 1 ensures a powerful vertical interconnection.

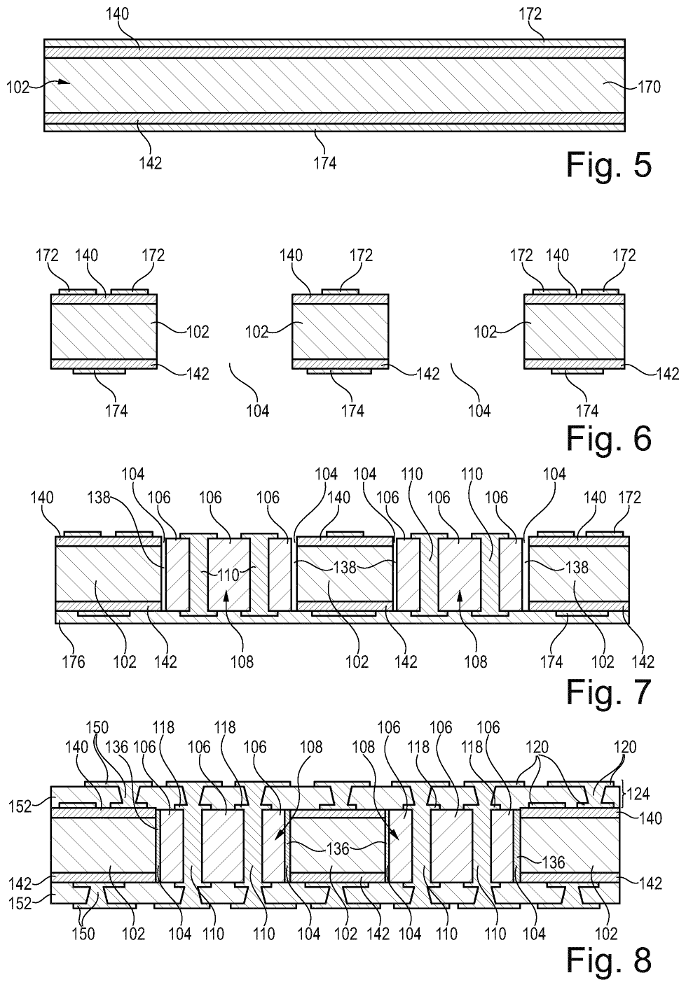

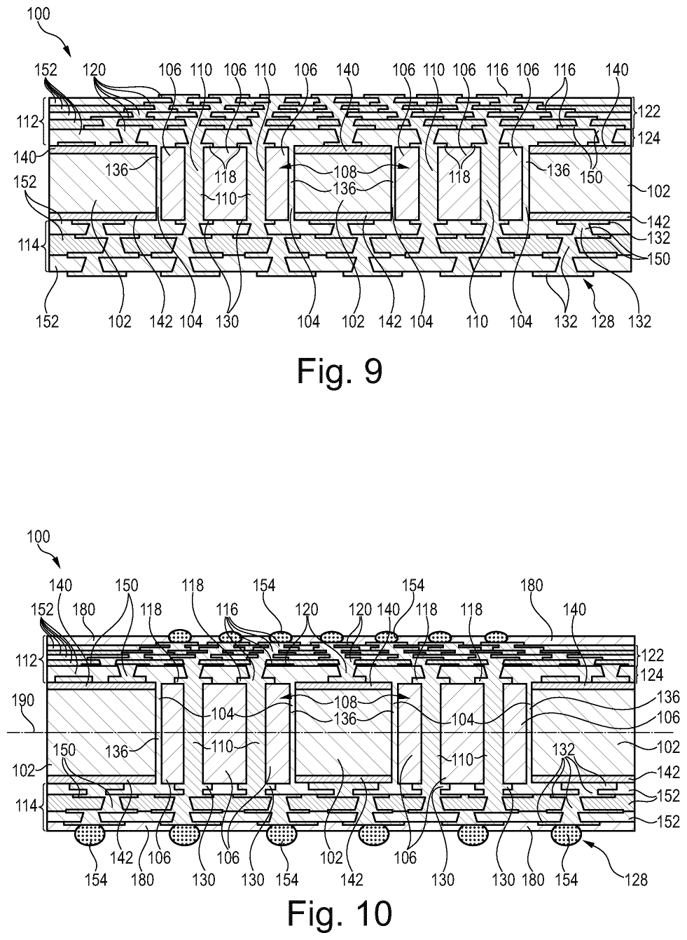

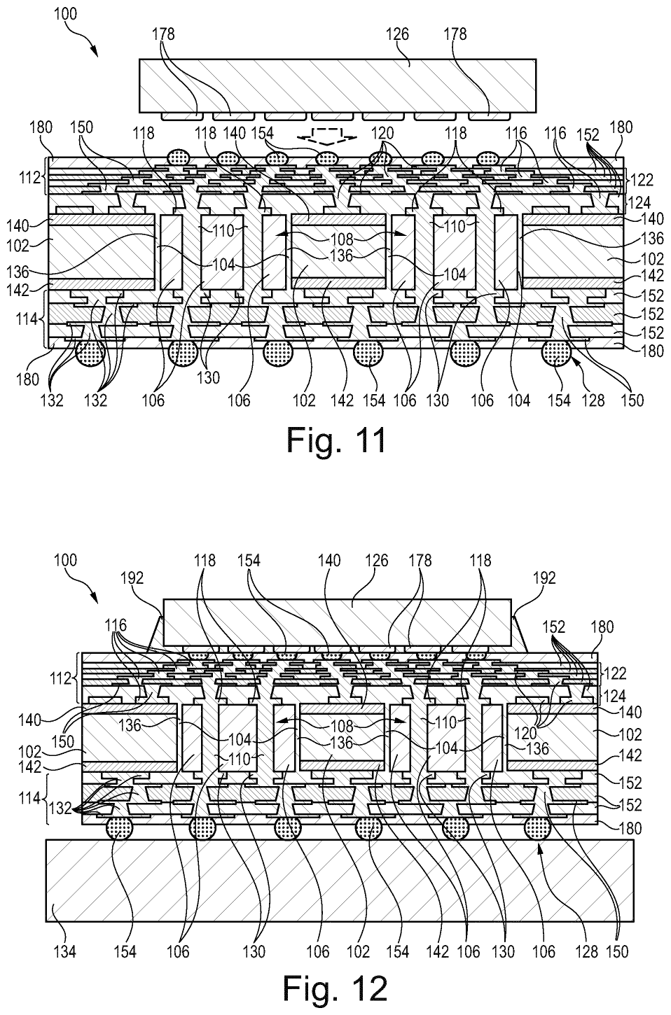

FIG. 2 to FIG. 12 illustrate cross-sectional views of structures obtained during carrying out a method of manufacturing a package 100, shown in FIG. 12, according to an exemplary embodiment of the disclosure. To put it shortly, the described manufacturing method may use a patterned glass carrier core with cavities as inorganic core 102 to improve layer routing and warpage behavior of the readily manufactured package 100.

Referring to FIG. 2, starting point may be a plate-shaped inorganic core 102 having an inorganic plate body 170 with a high vertical thickness, D, of for example at least 800 um. For instance, the inorganic core 102 may be embodied as glass body on with a Copper Clad Laminate (CCL), i.e. copper on a thin dielectric layer for glass reinforcement, may be formed. As shown, the inorganic plate body 170 (for instance consisting of glass) may be covered on both opposing main surfaces thereof with a respective adhesion promoting dielectric layer 140, 142. Furthermore, a metal layer 172, 174 (such as a copper foil) may be formed on each of the adhesion promoting dielectric layers 140, 142.

Referring to FIG. 3, the metal layers 172, 174 may be patterned by a subtractive process, for instance by etching. According to FIG. 3, the metal layers 172, 174 are structured in accordance with the same pattern on both opposing main surfaces.

Referring to FIG. 4, a cavity or through hole 104 is formed in the inorganic core 102. For example, this formation may be executed by a mechanical treatment or by laser processing.

FIG. 5 and FIG. 6 show corresponding patterning and cavity formation processes as FIG. 2 to FIG. 4 with the difference that a plurality of through holes 104 are formed in the inorganic core 102 according to FIG. 6. Furthermore, the patterning of the metal layers 172, 174 is different on the top side and on the bottom side according to FIG. 6.

Referring to FIG. 7, a temporary carrier 176 is attached to a bottom surface of the structure shown in FIG. 6 to close the through holes 104 from a bottom side. For instance, temporary carrier 176 may be a sticky tape. Thereafter, a respective organic board 108 is placed on the exposed sticky surface of the temporary carrier 176 and is thereby inserted into an assigned cavity or through hole 104. The organic boards 108 may be provided with an organic dielectric matrix 106 and mutually parallel elongate electrically conductive vertical through connections 110 extending through the entire organic dielectric matrix 106, as described referring to FIG. 1. Each organic board 108 is embedded in an assigned through hole 104. Hence, FIG. 7 illustrates taping and board bonding. Since the vertical through connections 110 extend through the entire thickness of the core 102 and board 108 and are exposed at both opposing main surfaces thereof (after removing temporary carrier 176, as described below), the vertical through connections 110 alone may establish an electric connection between a top side and a bottom side of the inorganic core 102.

Referring to FIG. 8, gaps 138 (see FIG. 7) between core 102 and boards 108 are filled with resin-type filling medium 136 using flowable and curable glue and/or by lamination. A first build-up is created by laminating layer structures 150, 152 on each of the two opposing main surfaces of core 102 and board 108. Said first build-up can be symmetric or substantially symmetric. Before forming the build-up on the bottom side, the temporary carrier 176 may be removed, for instance may be released or peeled off.

Referring to FIG. 9, a second build-up is created by laminating further layer structures 150, 152 on the first build-up on each of the two opposing main surfaces of core 102 and board 108. Said second build-up can be asymmetric. On the front side (see first laminated layer stack 112), a fan out redistribution layer is formed, whereas a normal build-up is formed on the back side (see second laminated layer stack 114). As a result, the first laminated layer stack 112 described referring to FIG. 1 is obtained on the upper main surface of core 102 and boards 108. Correspondingly, the second laminated layer stack 114 described referring to FIG. 1 is obtained on the lower main surface of core 102 and boards 108.

Referring to FIG. 10, a patterned solder resist 180 may be formed on both opposing main surfaces of the package 100 shown in FIG. 9. Furthermore, solder balls may be provided as electrically conductive connection structures 154 on exposed metallic surface areas on the top side and on the bottom side of the package 100. A central axis 190 in FIG. 10 shows that the build-up of the package 100 is not strictly symmetric (see layer stacks 112, 114).

Referring to FIG. 11, a component 126 embodied as semiconductor chip is surface mounted on the first laminated layer stack 112 according to FIG. 10. More specifically, electrically conductive pads 178 on a connection surface of the electronic component 126 are connected with the electrically conductive layer structures 150 of the first laminated layer stack 112 by electrically conductive connection structures 154. For instance, the electrically conductive connection structures 154 may be solder balls, so that a solder connection can be established between the first laminated layer stack 112 and surface mounted component 126. Hence, FIG. 10 illustrates a back-end process. The described chip last architecture provides a high manufacturing yield.

Referring to FIG. 12, the package 100 according to FIG. 11 is mounted on a component carrier-type mounting base 134, such as a printed circuit board (PCB). More specifically, exposed electrically conductive surface areas of the second laminated layer stack 114 can be electrically coupled with pads (not shown) of the mounting base 134 by electrically conductive connection structures 154, such as solder balls.

As a result of this manufacturing process, the package 100 according to FIG. 12 is obtained. This package 100 is a high yield fan out package. Advantageously, package 100 is in a proper packaging condition with high stiffness and chip last packaging process.

Furthermore, FIG. 12 shows that the surface mounted component 126 may be further protected mechanically and electrically by a dielectric protection structure 192.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A package, comprising:
an inorganic core having at least one through hole; and
at least one organic board comprising an at least partially organic dielectric matrix and at least one electrically conductive vertical through connection extending vertically through the at least partially organic dielectric matrix;
wherein the at least one organic board is at least partially embedded in the at least one through hole; and
wherein an electric connection between a top side and a bottom side of the inorganic core is established by the at least one electrically conductive vertical through connection.

2. The package according to claim 1, further comprising:
a first laminated layer stack on one of the top side and the bottom side of the inorganic core.

3. The package according to claim 2, wherein the first laminated layer stack comprises a redistribution structure.

4. The package according to claim 2, wherein electrically conductive traces of the first laminated layer stack are directly electrically connected with the at least one electrically conductive vertical through connection and/or with at least one horizontal connection element of the at least one organic board.

5. The package according to claim 2, wherein an integration density of electrically conductive elements in a first portion of the first laminated layer stack is larger than in a second portion of the first laminated layer stack.

6. The package according to claim 5, wherein the first portion faces away from the inorganic core and the second portion faces the inorganic core.

7. The package according to claim 2, comprising at least one component surface mounted on the first laminated layer stack.

8. The package according to claim 2, comprising a second laminated layer stack on the other one of the top side and the bottom side of the inorganic core, wherein the second laminated layer stack provides a grid array interface.

9. (canceled)

10. The package according to claim 8, wherein electrically conductive traces of the second laminated layer stack are directly electrically connected with the at least one electrically conductive vertical through connection and/or with at least one horizontal connection element of the at least one organic board.

11. The package according to claim 8, wherein an integration density of electrically conductive elements in the first laminated layer stack is larger than an integration density of electrically conductive elements in the second laminated layer stack.

12. The package according to claim 8, comprising a mounting base on which the second laminated layer stack is mounted.

13. The package according to claim 2, wherein at least one of a first width over which electric signals propagate through the first laminated layer stack and a second width over which electric signals propagate through the second laminated layer stack is larger than a constricted width over which electric signals propagate through the at least one organic board.

14. The package according to claim 1, comprising at least one of the following features:
a filling medium, in particular resin, at least partially filling at least one gap between a wall of the at least one organic board and a further wall of the inorganic core delimiting the at least one through hole;
wherein the filling medium bridges said wall of the at least one organic board and said further wall of the inorganic core, said wall of the at least one organic board has a different level of roughness compared with said further wall of the inorganic core;
wherein the at least one electrically conductive vertical through connection comprises at least one metal pillar, in particular at least one copper pillar, and/or at least one metal via;
wherein the inorganic core comprises glass, a ceramic and/or a semiconductor material

15.-16. (canceled)

17. The package according to claim 1, comprising at least one dielectric adhesion promoter layer on at least one of the top side and the bottom side of the inorganic core.

18. The package according to claim 1, wherein the inorganic core is free of electrically conductive through connections.

19. (canceled)

20. The package according to claim 1,
wherein the inorganic core has at least two through holes;
wherein the package comprises at least two organic boards, each comprising an at least partially organic dielectric matrix and at least one electrically conductive vertical through connection extending vertically through the at least partially organic dielectric matrix;
wherein each of the organic boards is embedded in a respective one of the through holes so that the organic boards are arranged side-by-side.

21. The package according to claim 1, wherein the at least one organic board comprises at least two electrically conductive vertical through connections extending in parallel through the at least partially organic dielectric matrix.

22. The package according to claim 1, wherein a vertical thickness of the inorganic core is at least 500 μm.

23. The package according to claim 1, wherein the electric connection between the top side and the bottom side of the inorganic core is established exclusively by the at least one electrically conductive vertical through connection.

24. A method of manufacturing a package, wherein the method comprising:
forming at least one through hole in an inorganic core;
providing at least one organic board with an at least partially organic dielectric matrix and at least one electrically conductive vertical through connection extending through the at least partially organic dielectric matrix;
embedding at least part of the at least one organic board in the at least one through hole; and
establishing an electric connection between a top side and a bottom side of the inorganic core by the at least one electrically conductive vertical through connection.
